(19) United States
(12) Patent Application Publication
(10) Pub. No.: US 2026/0119989 A1
(43) Pub. Date: Apr. 30, 2026

(54) CONTINUAL LEARNING SYSTEM AND CONTINUAL LEARNING METHOD

(71) Applicant: DENSO CORPORATION, Kariya-city (JP)

(72) Inventor: TARO MURAYAMA, Kariya-city (JP)

(21) Appl. No.: 19/364,454

(22) Filed: Oct. 21, 2025

(30) Foreign Application Priority Data
Oct. 25, 2024 (JP) 2024-188237

(51) Int. Cl. G06N 20/00; H03M 7/30

(52) U.S. Cl. CPC G06N 20/00; H03M 7/702

(57) ABSTRACT

A continual learning system learns a prediction model that performs prediction on input data, acquires additional data, learns the prediction model, calculates information on past data to be used in a next learning stage, and stores the learned prediction model and the calculated information on the past data. The continual learning system calculates the prediction model and the information of the past data, and calculates statistics of the past data. The statistics provides a learning result equivalent to a learning result obtained when the acquisition unit uses the past data acquired as the additional data in past by the acquisition unit.

### CROSS REFERENCE TO RELATED APPLICATION

The present application claims the benefit of priority from Japanese Patent Application No. 2024-188237 filed on Oct. 25, 2024. The entire disclosure of the above application is incorporated herein by reference.

### TECHNICAL FIELD

The present disclosure relates to a continual learning system for training a prediction model.

### BACKGROUND

For example, in a continual learning system as a comparative example, in order to increase the learning accuracy of a prediction model while limiting the number of learning data, useful data is selected and stored from additional data that is added as learning data each time learning is performed.

This type of continual learning system limits the amount of learning data that can be stored. Thereby, it is possible to shorten the learning time required to train the prediction model through the continual learning. It is also possible to reduce the capacity of a storage device that stores the learning data.

### SUMMARY

According to an aspect of the present disclosure, a continual learning system learns a prediction model that performs prediction on input data, acquires additional data, learns the prediction model, calculates information on past data to be used in a next learning stage, and stores the learned prediction model and the calculated information on the past data. The continual learning system calculates the prediction model and the information of the past data and calculates statistics of the past data. The statistics provides a learning result equivalent to a learning result obtained when the acquisition unit uses the past data acquired as the additional data in past by the acquisition unit.

### BRIEF DESCRIPTION OF THE DRAWINGS

FIG. 1 is a block diagram showing an overall configuration of a continual learning system according to an embodiment.

FIG. 2 is a block diagram showing a configuration of a prediction model according to the embodiment.

FIG. 3 is an explanatory diagram showing operations of continual learning in the continual learning system of the embodiment.

FIG. 4 is an explanatory diagram showing a processing operation in a learning unit according to a first embodiment.

FIG. 5 is an explanatory diagram showing a comparison of the data amounts in a storage when sufficient statistics calculated by a compression unit according to the first embodiment is stored and when all past data is stored.

FIG. 6 is an explanatory diagram showing a processing operation in a learning unit according to a second embodiment.

FIG. 7 is an explanatory diagram showing a processing operation in a learning unit according to a third embodiment.

FIG. 8 is a block diagram showing configurations of a cloud and vehicles according to other embodiments.

### DETAILED DESCRIPTION

However, in the above-described continual learning system, the amount of learning data (hereinafter referred to as past data) that can be stored is limited. Therefore, the phenomenon of forgetting knowledge gained from past data, known as catastrophic forgetting occurs, and a difficulty of reduced learning accuracy occurs.

Further, in the continual learning system, the amount of stored past data increases each time learning is performed. Therefore, even when the amount of stored past data is limited, the amount of past data stored in the storage device increases each time learning is performed. Hence, there is a difficulty that the time required to train the prediction model increases. Furthermore, since the past data stored in the storage device consists of learning data selected from additional data each time learning is performed, there is a difficulty of personal or confidential information being leaked if the learning data contains personal or confidential information.

One aspect of the present disclosure provides a continual learning system that accurately learns a prediction model while avoiding a risk of catastrophic forgetting and leakage of personal/confidential information, while reducing learning costs such as a storage capacity of learning data and learning time.

According to an aspect of the present disclosure, a continual learning system learns a prediction model that performs predictions for input data, and includes an acquisition unit, a learning unit, a compression unit, and a storage.

Of these, the acquisition unit acquires additional data, and the learning unit learns the prediction model based on the additional data, information on past data used in learning in the previous stage, and the prediction model learned in the previous stage. The compression unit calculates the information on the past data to be used in a next learning stage by the learning unit based on the additional data, the information on the past data, and the prediction model learned in the previous learning stage by the learning unit.

The storage stores the prediction model learned by the learning unit and the information on the past data calculated by the compression unit. The learning unit and the compression unit calculate the prediction model and the information of the past data based on the additional data acquisition by the acquisition unit, the prediction model stored in the storage, and the information on the past data stored in the storage.

When, in the next learning stage, the learning unit further learns, as the information on the past data, the additional data for the next learning stage, the compression unit calculates statistics of the past data. The statistics provides a learning result equivalent to a learning result obtained when the acquisition unit uses the past data acquired by the acquisition unit in past as the additional data.

In this way, in the continual learning system of the present disclosure, the information on past data stored in the storage is not a portion of past data selected from the past data, but is a statistical quantity of the past data.

Here, the statistics are the amount calculated from a data set. In the present disclosure, the compression unit calculates the statistics as statistics of past data, which provides learning results equivalent to those obtained when using the past data itself when learning in the next stage together with the additional data in the next stage. In other words, the statistics of the past data are calculated so that, during learning in the next stage, the learning unit obtains learning results equivalent to those obtained when learning additional data 36(t+1) in the next stage together with past data 36(0), 36(1), 36(2), . . . 36(t).

Therefore, the compression unit can perform data compression that can be used for continual learning on all past data acquired as additional data by the acquisition unit. Therefore, in the learning unit, based on the additional data, the statistics of past data used in the previous learning stage, and the prediction model learned in the previous stage, it is possible to accurately learn the prediction model while avoiding the risk of catastrophic forgetting and the leakage of personal/confidential information. In the present disclosure, personal information refers to, for example, ordinary pedestrians that appear in images when automobile traveling data is used as learning data. The confidential information is information that should only be seen by people with higher authority, for example, when internal company documents are used as learning data (text). However, the form of the training data is not limited to images or text, and may be other forms such as audio or natural language, for example.

Furthermore, since the statistics of past data are stored in the storage, it is possible to reduce the storage capacity of the past data stored in the storage compared to when the past data is stored in the storage as is. Therefore, according to the continual learning system of the present disclosure, compared to the technology of the comparative example described above, it is possible to reduce learning costs, specifically the storage capacity of past data in the storage and the time required for the learning unit to learn a prediction model.

Hereinafter, embodiments of the present disclosure will be described with reference to the drawings.

### Configuration of Continual Learning System

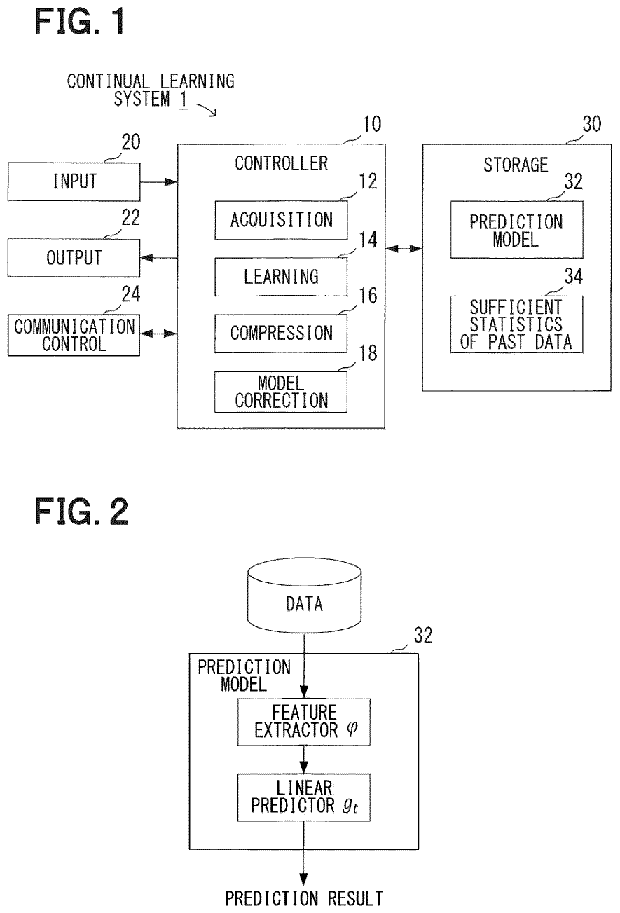

A continual learning system 1 according to the present embodiment is a computer system implemented by a general-purpose computer such as a personal computer and peripheral devices. As shown in FIG. 1, the continual learning system 1 includes a controller 10, an input unit 20, an output unit 22, a communication control unit 24, and a storage 30.

The input unit 20 is implemented using input devices such as a keyboard and a mouse, and inputs various instruction information such as an instruction to start processing to the controller 10 in response to input operations by an operator. The input unit 20 has a function of inputting an importance ratio γt of additional data relative to past data, which will be described later.

The output unit 22 is implemented by a display device such as a liquid crystal display, a printing device such as a printer, or the like. The communication control unit 24 is implemented by a NIC (Network Interface Card) or the like, and controls communication between the controller 10 and an external device such as a server via a network.

Next, the storage 30 is implemented by a semiconductor memory element such as a RAM (Random Access Memory) or a flash memory, or a storage device such as a hard disk or an optical disk. The storage 30 stores a processing program for performing continual learning and various data used during execution of the processing program.

The storage 30 also stores a prediction model 32 generated in the continual learning process and sufficient statistics 34 of the past data used to generate the prediction model 32. The controller 10 is implemented using a CPU (Central Processing Unit) or the like, and executes processing programs stored in the storage 30. As a result, the controller 10 functions as an acquisition unit 12, a learning unit 14, a compression unit 16, and a model correction unit 18, and executes the continual learning process. Each or some of these functional units may be implemented in different hardware. For example, the learning unit 14 and the compression unit 16 may be implemented as devices separate from other functional units.

Here, the acquisition unit 12 acquires the learning data input from the input unit 20 or the communication control unit 24 as additional data for learning, and transfers it to the learning unit 14 and the compression unit 16. The learning unit 14 learns the prediction model 32 using the additional data acquired by the acquisition unit 12, the prediction model 32 learned in the previous stage, and sufficient statistics 34 of the past data.

As shown in FIG. 2, the prediction model 32 generated by the learning unit 14 is a well-known model that includes a feature extractor φ (or φt) and a linear predictor gt including learned parameters. In the prediction model 32, input data input from the input unit 20 or the communication control unit 24 during learning passes through the feature extractor φ (or φt) and the linear predictor φt, and is output as a prediction result.

The learning unit 14 uses the prediction model 32 stored in the storage 30 and sufficient statistics 34 of past data to learn the prediction model 32. The prediction model 32 stored in the storage 30 is updated to the learned prediction model 32 every time the learning unit 14 learns the prediction model 32.

Next, the compression unit 16 calculates sufficient statistics 34 of the past data including the additional data using the additional data acquired by the acquisition unit 12, the prediction model 32 learned in the previous stage, and sufficient statistics 34 of the past data, which is the learning data used in the previous stage of learning.

In addition, the calculation of the sufficient statistics 34 in the compression unit 16 uses the prediction model 32 stored in the storage 30 and the sufficient statistics 34 of past data, similarly to the learning of the prediction model 32 in the learning unit 14. Furthermore, the sufficient statistics 34 of the past data stored in the storage 30 are updated to the calculated sufficient statistics 34 every time the compression unit 16 calculates the sufficient statistics 34.

The model correction unit 18 also has a function of changing the configuration of the linear predictor gt in the prediction model 32. That is, for example, in a case where the loss function (described later) used when the learning unit 14 learns the prediction model 32 is squared error and the prediction model 32 is a linear regression model having an arbitrary feature extractor, when the number of classes in the learning data increases from 1 to K (where K>2), the linear predictor gt is corrected as bellow.

$$Linear predictor ( before correction ) {g}_{t} : {ℝ}^{D} \to ℝ : {g}_{t} ( x ) = {\hat{β}}_{t}^{T} x \qquad ( First Equation )$$

$${\hat{β}}_{t} ∈ {ℝ}^{D} : Learned parameter$$

$$Linear predictor ( after correction ) {g}_{t} : {ℝ}^{D} \to {ℝ}^{K} : {g}_{t} ( x ) = {\hat{B}}_{t}^{T} x$$

$${\hat{B}}_{t} ∈ {ℝ}^{D \times K} : Learned parameter$$

### Continual Learning Process

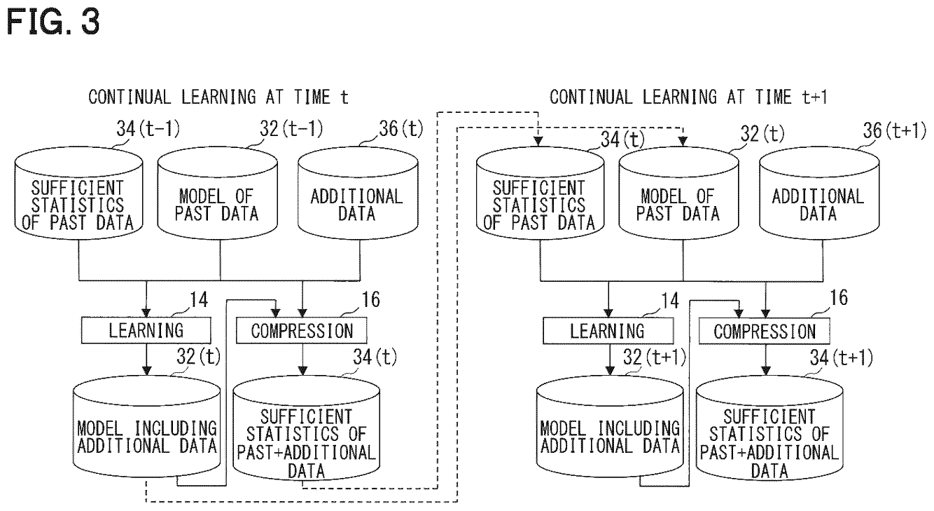

Next, the continual learning process in the controller 10 is executed by repeatedly learning the prediction model 32 at each learning time, such as at a previous learning time t, a next learning time t+1, and the like, as shown in FIG. 3.

That is, in the continual learning process at time t, the learning unit 14 calculates a prediction model 32(t) based on a prediction model 32(t−1) generated based on past data including additional data during learning in the previous stage, a sufficient statistic 34(t−1) of that past data, and the current additional data 36(t).

Furthermore, the compression unit 16 calculates sufficient statistics 34(t) of the past data based on statistics 34(t−1) of the past data including the additional data calculated during the previous learning stage, the prediction model 32(t−1) generated during the previous learning stage, and the current additional data 36(t).

Next, in the continual learning process at time t+1, the learning unit 14 calculates a prediction model 32(t+1) based on a prediction model 32(t) generated based on past data including additional data during the previous learning stage, sufficient statistics 34(t) of that past data, and the current additional data 36(t+1).

Furthermore, the compression unit 16 calculates sufficient statistics 34(t+1) of the past data based on statistics 34(t) of the past data including the additional data calculated during the previous learning stage, the prediction model 32(t) generated during the previous learning stage, and the current additional data 36(t+1).

Therefore, in the continual learning system 1 of the present embodiment, the prediction model 32 and sufficient statistics 34 of past data in the storage 30 are repeatedly calculated and updated for each learning time t, t+1, . . . of the continual learning process.

### Effects

As described above, the past data used in the continual learning process of the present embodiment is not all of the learning data used in past continuous learning, but rather sufficient statistics of that learning data.

Therefore, the amount of past data stored in the storage 30 does not increase each time the prediction model 32 is trained, as would be the case if all learning data used in past continual learning were stored in the storage 30 as past data.

Therefore, according to the continual learning system 1 of the present embodiment, it is possible to reduce the storage capacity of the storage 30 for storing past data. Furthermore, it is possible to reduce the processing load in the continual learning process, and shorten the time required for the continual learning process. Therefore, according to the continual learning system 1 of the present embodiment, it is possible to reduce these learning costs.

Further, the sufficient statistics are statistics that provide exactly the same information as the raw data set in model training. Therefore, by using the sufficient statistics 34 of the past data stored in the storage 30 in the learning unit 14, it is possible to learn the prediction model 32 with the same accuracy as when a raw data set is used as the past data. Therefore, according to the continual learning system 1 of the present embodiment, it is possible to accurately learn the prediction model 32 while avoiding the risk of catastrophic forgetting and the leakage of personal/confidential information.

Furthermore, the continual learning system 1 of the present embodiment includes the model correction unit 18 capable of changing the configuration of the linear predictor gt in the prediction model 32. Therefore, it is possible to respond not only to situations in which learning data is added, but also to situations in which classes are added.

Next, more detailed configuration examples of the learning unit 14 and the compression unit 16 of the present embodiment will be described in the following first to third embodiments. The definitions of terms and symbols used in the following description of the first to third embodiments are as shown in first and second tables below.

(First Table)

Arbitrary Fixed Feature Extractor:
φ: [symbol] → [symbol]
(Note: “fixed” means it does not include learnable parameters.)
Linear Model: A function that is linear with respect to its parameters.
Whether the function is linear or nonlinear with respect to the input
data does not matter.
Past Data (dataset obtained at time t−1):
Xₜ₋₁ ∈ [symbol] , Φₜ₋₁ ∈ [symbol] , yₜ₋₁ ∈ [symbol]
Additional Data (dataset obtained at time t):
Xₜ ∈ [symbol] , Φₜ ∈ [symbol] , yₜ ∈ [symbol]
Sufficient Statistic at Time t (Matrix Form):
S_{xx,t} ∈ [symbol] , S_{xy,t} ∈ [symbol] ... First Embodiment
Sufficient Statistic at Time t (Synthetic Data Form in Feature Space):
\tilde{Φ}ₜ ∈ [symbol] , \tilde{y}ₜ ∈ [symbol] ... Second Embodiment
Sufficient Statistic at Time t (Synthetic Data Form in Feature Space):
\tilde{X}_{t′} ∈ [symbol] , \tilde{y}ₜ ∈ [symbol] , \tilde{w}ₜ ∈ [symbol] ... Third Embodiment
L2 Regularization Coefficient at Time t: λₜ ∈ [symbol]
(The type of regularization does not matter.)
Kernel: k: [symbol] × [symbol] →

[symbol]

(Second Table)

n: Number of data points
X, y: Samples (design matrix), labels
ₜ: Subscript indicating quantities obtained at time t
d: Dimension of input space
D: Dimension of feature space
Φ: Image of X mapped by φ (design matrix)
\tilde{ }: Decoration indicating synthetic data
w: Weight
⊙: Element-wise product
′: Decoration indicating differentiation

The fixed feature extractor listed in the first table, a L2 regularization coefficient at time t, the kernel, and the dimension of the feature space listed in the second table are specified in advance by a user via the input unit 20 or the communication control unit 24. However, by setting default values in advance, the continual learning system 1 can be operated without the user providing these. Here, the default value of the fixed feature extractor can be, for example, Random Fourier Feature in the first and second embodiments described below. Furthermore, the default value of the L2 regularization coefficient at time t can be, for example, 1e-6 to 1e6, which can be used for grid search. Furthermore, the default value of the kernel can be, for example, an RBF kernel in the third embodiment described later. Furthermore, the default value of the dimension of the feature space can be set to, for example, 10,000 in the first and second embodiments described below.

### First Embodiment

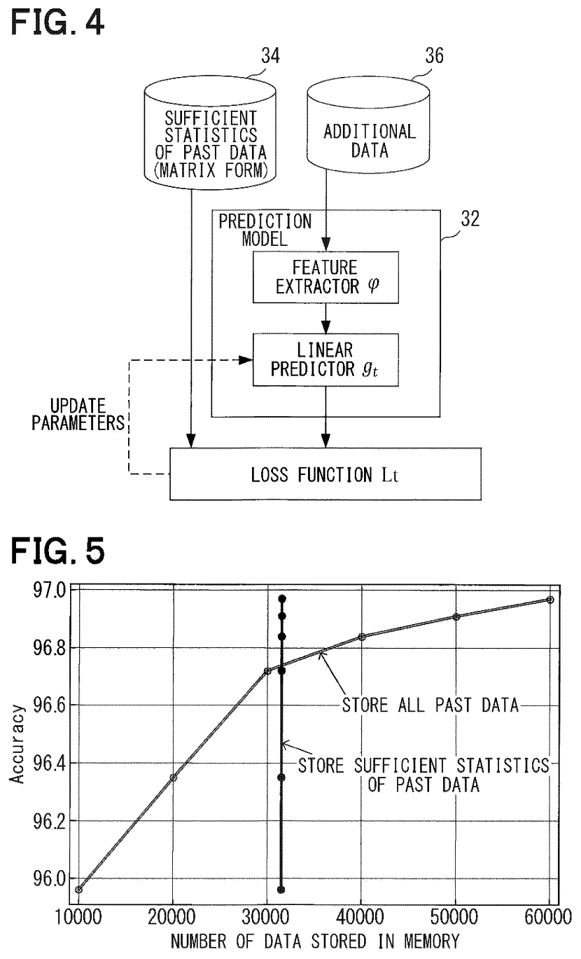

In the first embodiment, the processing operations of the learning unit 14 and the compression unit 16 in a case where the sufficient statistics 34 of the past data are in the matrix format shown in the first table will be described. As shown in FIG. 4, in the learning process of the present embodiment executed by the learning unit 14, sufficient statistics 34 of Sxx, t−1, Sxy, t−1 for past data are input to a loss function Lt. The additional data 36 of Xt, yt is passed through the feature extractor φ and the linear predictor gt, and then input to the loss function Lt. Then, the parameter β of the linear predictor gt is iteratively updated so as to minimize the loss function Lt, and the learned parameter βt is calculated.

The specific forms of the feature extractor φ, the linear predictor gt, and the loss function Lt are determined by the prediction model 32. For example, when the loss function Lt is the squared error and the prediction model 32 is the linear regression model with the arbitrary feature extractor φ, the prediction model 32 is shown as bellow.

$${f}_{t} ( x ) = {g}_{t} ( φ ( x ) ) \qquad ( Second Equation )$$

$$Feature extractor :$$

$$φ ( x )$$

$$Linear predictor :$$

$${g}_{t} ( x ) = {\hat{β}}_{t}^{T} x$$

In this case, the learning unit 14 calculates parameters that minimize the following loss function Lt as bellow. Here, an example of ridge regression is shown.

$$Loss function : \qquad ( Third Equation )$$

$${L}_{t} ( β ) = \frac{1}{2} ( {β}^{T} {S}_{xx , t - 1} β - 2 {β}^{T} {S}_{xy , t - 1} ) + \frac{1}{2} {\sum }_{i = 1}^{{n}_{t}} {( {φ ( {x}_{i} )}^{T} β - {y}_{i} )}^{2} + \frac{{λ}_{t}}{2} {‖ β ‖}^{2}$$

$$Parameter :$$

$${\hat{β}}_{t} ∈ {ℝ}^{D}$$

Furthermore, the compression unit 16 receives, as input, the sufficient statistics of the past data in the first embodiment shown in the first table, additional data Xt, yt, and the importance ratio γt of the additional data relative to the past data, and calculates the sufficient statistics of the past+additional data as below.

$${S}_{xx , t} = {S}_{xx , t - 1} + {Y}_{t} {\sum }_{i = 1}^{{n}_{t}} φ ( {x}_{i} ) {φ ( {x}_{i} )}^{T} \qquad ( Fourth Equation )$$

$${S}_{xy , t} = {S}_{xy , t - 1} + {Y}_{t} {\sum }_{i = 1}^{{n}_{t}} φ ( {x}_{i} ) {y}_{i}$$

The importance ratio γt of the additional data is a parameter input from the outside via the input unit 20. Therefore, the operator can specify the ratio of importance to be attached to the past and additional data by operating the input unit 20, and for example, compression can be performed with greater importance attached to the additional data.

### Experimental Results

FIG. 5 shows the results of an experiment conducted to confirm the effect of the present embodiment. As shown in FIG. 5, the sufficient statistics of the past data calculated by the compression unit 16 as described above does not increase the amount of data each time the continual learning process is executed, as occurs when all learning data is stored as past data. The sufficient statistics remains a constant amount of data.

Furthermore, when the prediction model 32 is trained using all the training data as past data, the “Accuracy” that represents the accuracy of the training improves as the amount of past data increases, and it was confirmed that the accuracy of the training also changes in a similar manner in the present embodiment.

Therefore, according to the present embodiment, it is possible to completely avoid catastrophic forgetting, similar to the case where all learning data is accumulated as past data, while the amount of sufficient statistics to be stored as past data in the storage 30 is kept constant.

FIG. 5 shows experimental results of the learning accuracy when the prediction model 32 is trained using a MNIST (Modified National Institute of Standards and Technology) dataset in which 10,000 pieces of data are added at a time. In this experiment, the fixed feature extractor was Random fourier features, the number of feature dimensions was D=5000, and the L2 regularization coefficient was 1e-5 to 1, using grid search.

### Modification

In the present modification, a case will be described in which the loss function Lt is a squared error and the prediction model 32 is a linear model having an arbitrary feature extractor φ.

Examples of such models include SVM (Support Vector Machine), whose corresponding loss function is smoothed hinge loss, and logistic regression, whose corresponding loss function is cross entropy loss. Here, an example of SVM is shown.

In this case, the prediction model 32 is written as follows:

$${f}_{t} ( x ) = {g}_{t} ( φ ( x ) ) \qquad ( Fifth Equation )$$

$$Feature extractor$$

$$φ ( x )$$

$$Linear predictor$$

$${g}_{t} ( x ) = sign ( {\hat{β}}_{t}^{T} x )$$

Then, the learning unit 14 calculates parameters that minimize the following loss function Lt.

$$Loss function : \qquad ( Sixth Equation )$$

$${L}_{t} ( β ) = \frac{1}{2} ( {β}^{T} {S}_{xx , t - 1} β - 2 {β}^{T} {S}_{xy , t - 1} ) + {\sum }_{i = 1}^{{n}_{t}} l ( {z}_{i}^{T} β ) + \frac{{λ}_{t} - {λ}_{t - 1}}{2} {‖ β ‖}^{2}$$

$$Parameter :$$

$${\hat{β}}_{t} ∈ {ℝ}^{D}$$

$${z}_{i} = {y}_{i} φ ( {x}_{i} )$$

$$l : Following smoothed hinge loss$$

$$l ( x ) = G ( \frac{1 - x}{σ} ) ( 1 - x ) + g ( \frac{1 - x}{σ} ) σ$$

$$g : Probability density function of the standard normal distribution$$

$$G : Its cumulative distribution function$$

$$σ : Arbitrary scalar parameter$$

More information on smooth hinge loss is described in a non-patent document “Luo, Junru, Hong Qiao, and Bo Zhang. “Learning with Smooth Hinge Losses.”, 2021″. A stationary condition and a second-order Taylor approximation can be used to derive these.

Next, the compression unit 16 receives as input the sufficient statistics of the past data shown in the first table, the additional data Xt, yt, the L2 regularization coefficient λt, the learned parameter βt, and the importance ratio γt of the additional data relative to the past data, and calculates the sufficient statistics of the past+additional data below.

$${S}_{xx , t} = {S}_{xx , t - 1} + {Y}_{t} ( {\sum }_{i = 1}^{{n}_{t}} {l}^{″} ( {z}_{i}^{T} {\hat{β}}_{t} ) {z}_{i} {z}_{i}^{T} + {λ}_{t} I ) \qquad ( Seventh Equation )$$

$${S}_{xy , t} = {S}_{xy , t - 1} + {Y}_{t} ( {\sum }_{i = 1}^{{n}_{t}} {l}^{″} ( {z}_{i}^{T} {\hat{β}}_{t} ) {z}_{i} {z}_{i}^{T} + {λ}_{t} I ) {\hat{β}}_{t}$$

### Second Embodiment

In the second embodiment, the processing operations of the learning unit 14 and the compression unit 16 in a case where the sufficient statistics 34 of the past data are in the synthetic data format in the feature space shown in the first table will be described.

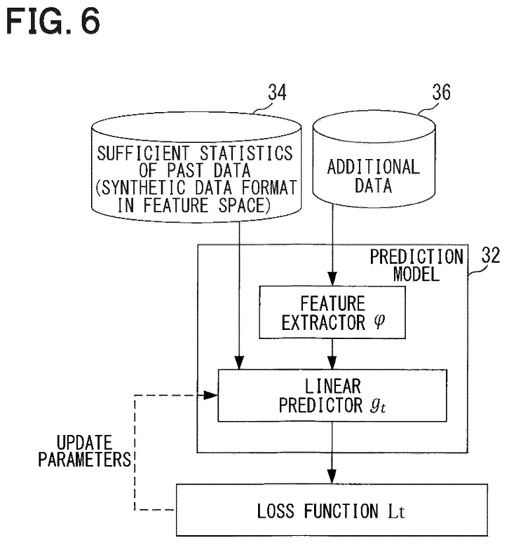

As shown in FIG. 6, in the learning process of the present embodiment executed by the learning unit 14, sufficient statistics 34 of past data Φt−1, yt−1 are passed through the linear predictor gt and then input to a loss function Lt. The additional data Xt, yt are passed through the feature extractor φ and the linear predictor gt, and then input to the loss function Lt. Then, a parameter β of the linear predictor gt is iteratively updated so as to minimize the loss function Lt, and the learned parameter βt is obtained.

The specific forms of the feature extractor φ, the linear predictor gt, and the loss function Lt are determined by the prediction model 32. For example, when the loss function Lt is the squared error and the prediction model 32 is the linear regression model having the arbitrary feature extractor φ, the prediction model 32 is shown by the second equation in the first embodiment.

In this case, the learning unit 14 calculates parameters that minimize the following loss function Lt. Here, an example of ridge regression is shown.

$$Loss function : \qquad ( Eigth Equation )$$

$${L}_{t} ( β ) = \frac{1}{2} {\sum }_{i = 1}^{{\tilde{n}}_{t - 1}} {( {( {\tilde{φ}}_{t - 1} )}_{i}^{T} β - {\tilde{y}}_{t - 1} )}^{2} + \frac{1}{2} {\sum }_{i = 1}^{{n}_{t}} {( {φ ( {x}_{i} )}^{T} β - {y}_{i} )}^{2} + \frac{{λ}_{t}}{2} {‖ β ‖}^{2}$$

$$Parameter :$$

$${\hat{β}}_{t} ∈ {ℝ}^{D}$$

Furthermore, the compression unit 16 receives as input the sufficient statistics of the past data in the second embodiment shown in the first table, the additional data Xt, yt, and the importance ratio γt of the additional data relative to the past data, and calculates the sufficient statistics of the past+additional data as below. Specifically, calculation is performed based on the following equation.

$${Φ}_{t}^{*} = ( \begin{matrix}{\tilde{Φ}}_{t - 1} \\ \sqrt{{γ}_{t}} {Φ}_{t}\end{matrix} ) ∈ {ℝ}^{{n}_{t}^{*} \times D} , {y}_{t}^{*} = ( \begin{matrix}{\tilde{y}}_{t - 1} \\ \sqrt{{γ}_{t}} {y}_{t}\end{matrix} ) ∈ {ℝ}^{{n}_{t}^{*}} \qquad ( Ninth Equation )$$

$${n}_{t}^{*} = {\tilde{n}}_{t - 1} + {n}_{t}$$

$${Φ}_{t}^{*} = {U}_{t}^{*} {M}_{t}^{*} {V}_{t}^{* T} \qquad ( Tenth Equation )$$

After performing singular value decomposition as above, an arbitrary R×R orthogonal matrix U (usually, choosing U=I (unit matrix) is sufficient) is specified, and the corresponding sufficient statistics (synthetic data format in feature space) are calculated as bellow.

$${\tilde{Φ}}_{t} = \tilde{U} {M}_{t}^{*} {V}_{t}^{* T} , {\tilde{y}}_{t} = \tilde{U} {U}_{t}^{* T} {y}_{t}^{*} \qquad ( Eleventh Equation )$$

(The number of synthetic data ñₜ is the rank R of Φ*ₜ, and is adaptively determined)

### Third Embodiment

In the third embodiment, the processing operations of the learning unit 14 and the compression unit 16 in a case where the sufficient statistics of the past data are in the synthetic data format in an input space shown in the first table will be described.

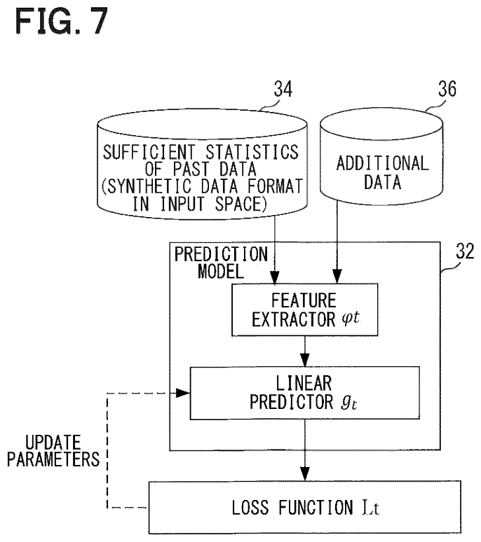

As shown in FIG. 7, in the present embodiment, in the learning process executed by the learning unit 14, sufficient statistics 34 of past data Xt−1, yt−1, wt−1 are input to the loss function Lt after passing through the feature extractor φ and the linear predictor gt. The additional data Xt, yt are also input to the loss function Lt after passing through the feature extractor φt and the linear predictor gt. Then, the parameter α of the linear predictor gt is iteratively updated so as to minimize the loss function Lt, and the learned parameter αt is calculated.

The specific forms of the feature extractor φt, the linear predictor gt, and the loss function Lt are determined by the prediction model 32. For example, when the loss function Lt is the squared error and the prediction model 32 is the linear regression model with an arbitrary feature extractor (kernel), the prediction model 32 is written as bellow.

$${f}_{t} ( x ) = {g}_{t} ( {φ}_{t} ( x ) ) \qquad ( Twelfth Equation )$$

$$Feature extractor ( kernel )$$

$${φ}_{t} ( x ) = k ( x , {X}_{t}^{*} )$$

$$Liner predictor$$

$${g}_{t} ( x ) = {\hat{α}}_{t}^{T} x$$

In this case, the learning unit 14 calculates parameters that minimize the following loss function Lt. Here, an example of kernel ridge regression is shown.

$$Loss function : \qquad ( Thirteenth Equation )$$

$${L}_{t} ( α ) = \frac{1}{2} {‖ {W}_{t}^{* \frac{1}{2}} {K}_{{X}_{t}^{*} {X}_{t}^{*}} α - {y}_{t}^{*} ‖}^{2} + \frac{{λ}_{t}}{2} {α}^{T} {K}_{{X}_{t}^{*} {X}_{t}^{*}} α$$

$$Parameter :$$

$${\hat{α}}_{t} ∈ {ℝ}^{{n}_{t}^{*}}$$

$${n}_{t}^{*} = {\tilde{n}}_{t - 1} + {n}_{t}$$

$${L}_{t} ( α ) = \frac{1}{2} {‖ {W}_{t}^{* \frac{1}{2}} {K}_{{X}_{t}^{*} {X}_{t}^{*}} α - {y}_{t}^{*} ‖}^{2} + \frac{{λ}_{t}}{2} {α}^{T} {K}_{{X}_{t}^{*} {X}_{t}^{*}} α$$

Furthermore, the compression unit 16 receives as input the sufficient statistics of the past data in the first embodiment shown in the first table, the additional data Xt, yt, the L2 normalization coefficient λt, and the importance ratio γt of the additional data relative to the past data, and calculates the sufficient statistics of the past+additional data below. Specifically, sufficient statistics that minimize the following loss function are obtained by iterative calculation.

$$Loss function : \qquad ( Fourteenth Equation )$$

$${L}_{t}^{distill} ( \tilde{X} , \tilde{y} , \tilde{w} ) = tr ( \tilde{W} {K}_{\tilde{X} \tilde{X}} \tilde{W} {K}_{\tilde{X} \tilde{X}} ) - 2 tr ( \tilde{W} {K}_{\tilde{X} {X}_{t}^{*}} {W}_{t}^{( γ ) *} {K}_{{X}_{t}^{*} \tilde{X}} ) + tr ( {W}_{t}^{( γ ) *} {K}_{{X}_{t}^{*} {X}_{t}^{*}} {W}_{t}^{( γ ) *} {K}_{{X}_{t}^{*} {X}_{t}^{*}} ) + {\tilde{y}}_{t}^{T} {\tilde{W}}^{\frac{1}{2}} {K}_{\tilde{X} \tilde{X}} {\tilde{W}}^{\frac{1}{2}} {\tilde{y}}_{t} - 2 {\tilde{y}}^{T} {\tilde{W}}^{\frac{1}{2}} {K}_{\tilde{X} {X}_{t}^{*}} {W}_{t}^{( γ ) * \frac{1}{2}} {y}_{t}^{*} + {y}_{t}^{* T} {W}_{t}^{( γ ) * \frac{1}{2}} {K}_{{X}_{t}^{*} {X}_{t}^{*}} {W}_{t}^{( γ ) * \frac{1}{2}} {y}_{t}^{*}$$

$${\tilde{n}}_{t} : Synthetic data ( Hyper parameter )$$

$$\tilde{W} = diag ( \tilde{w} ) {W}_{t}^{( γ ) *} = diag ( ( \begin{matrix}{\tilde{w}}_{t - 1} \\ {γ}_{t} {1}_{{n}_{t}}\end{matrix} ) ) ∈ {ℝ}^{{n}_{t}^{*} \times {n}_{t}^{*}}$$

$$Sufficient statistics :$$

$${\tilde{X}}_{t} ∈ {ℝ}^{{\tilde{n}}_{t} \times d} , {\tilde{y}}_{t} ∈ {ℝ}^{{\tilde{n}}_{t}} , {\tilde{w}}_{t} ∈ {ℝ}^{{\tilde{n}}_{t}}$$

### Modification

In the present modification, a case will be described in which the loss function Lt is the squared error and the prediction model 32 is the linear model having the arbitrary feature extractor (kernel).

Examples of such models include SVM, whose corresponding loss function is smoothed hinge loss, and logistic regression, whose corresponding loss function is cross entropy loss. Here, an example of SVM is shown.

In this case, the prediction model 32 is shown as bellow.

$${f}_{t} ( x ) = {g}_{t} ( {φ}_{t} ( x ) ) \qquad ( Fifteenth Equation )$$

$$Feature extractor$$

$${φ}_{t} ( x ) = k ( x , {X}_{t}^{*} )$$

$$Liner predictor$$

$${g}_{t} ( x ) = sign ( {\hat{α}}_{t}^{T} x )$$

Then, the learning unit 14 calculates parameters that minimize the following loss function Lt.

$$Loss function : \qquad ( Sixteenth Equation )$$

$${L}_{t} ( α ) = {W}_{t}^{* T} l ( {y}_{t}^{*} ⊙ {K}_{{X}_{t}^{*} {X}_{t}^{*}} α ) + \frac{{λ}_{t}}{2} {α}^{T} {K}_{{X}_{t}^{*} {X}_{t}^{*}} α$$

$$Parameter :$$

$${\hat{α}}_{t} ∈ {ℝ}^{{n}_{t}^{*}}$$

$$l acts element - wise .$$

$${X}_{t}^{*} = ( \begin{matrix}{\tilde{X}}_{t - 1} \\ {X}_{t}\end{matrix} ) ∈ {ℝ}^{{n}_{t}^{*} \times d} , {y}_{t}^{*} = ( \begin{matrix}{\tilde{y}}_{t - 1} \\ {y}_{t}\end{matrix} ) ∈ {ℝ}^{{n}_{t}^{*}} , {W}_{t}^{*} = diag ( ( \begin{matrix}{\tilde{w}}_{t - 1} \\ {1}_{{n}_{t}}\end{matrix} ) ) ∈ {ℝ}^{{n}_{t}^{*} \times {n}_{t}^{*}}$$

Next, the compression unit 16 receives, as input, the sufficient statistics of the past data shown in the first table, the additional data Xt, yt, the L2 regularization coefficient λt, the learned parameter αt, and the importance ratio γt of the additional data relative to the past data, and calculates the sufficient statistics of the past+additional data below. Specifically, sufficient statistics that minimize the following loss function are obtained by iterative calculation.

$$Loss function : \qquad ( Seventeenth Equation )$$

$${L}_{c}^{distill} ( \tilde{X} , \tilde{y} , \tilde{w} ) = {\tilde{c}}_{t}^{T} {K}_{\tilde{X} \tilde{X}} {\tilde{c}}_{t} + 2 {λ}_{t} {\tilde{c}}_{t}^{T} {K}_{\tilde{X} {X}_{t}^{*}} {\hat{α}}_{t} + {λ}_{t}^{2} {\hat{α}}_{t}^{T} {K}_{{X}_{t}^{*} {X}_{t}^{*}} {\hat{α}}_{t} + tr ( {\tilde{A}}_{t} {K}_{\tilde{X} \tilde{X}} {\tilde{A}}_{t} {K}_{\tilde{X} \tilde{X}} ) - 2 tr ( {\tilde{A}}_{t} {K}_{\tilde{X} {X}_{t}^{*}} {B}_{t}^{*} {K}_{{X}_{t}^{*} \tilde{X}} ) + tr ( {B}_{t}^{*} {K}_{{X}_{t}^{*} {X}_{t}^{*}} {B}_{t}^{*} {K}_{{X}_{t}^{*} {X}_{t}^{*}} )$$

$${\tilde{n}}_{t} : Synthetic data ( Hyper parameter )$$

$${l}^{′} , {l}^{″} : acts element - wise$$

$$\tilde{W} = diag ( \tilde{w} ) {w}_{t}^{( γ ) *} = ( \begin{matrix}{\tilde{w}}_{t - 1} \\ {γ}_{t} {1}_{{n}_{t}}\end{matrix} ) ∈ {ℝ}^{{n}_{t}^{*}}$$

$${\tilde{A}}_{t} = diag ( \tilde{w} ⊙ \tilde{y} ⊙ \tilde{y} ⊙ {l}^{″} ( \tilde{y} ⊙ {K}_{\tilde{X} {X}_{t}^{*}} {\hat{α}}_{t} ) )$$

$${B}_{t}^{*} = diag ( {w}_{t}^{( γ ) *} ⊙ {y}_{t}^{*} ⊙ {y}_{t}^{*} ⊙ {l}^{″} ( {y}_{t}^{*} ⊙ {K}_{{X}_{t}^{*} {X}_{t}^{*}} {\hat{α}}_{t} ) )$$

$${\tilde{c}}_{t} = \tilde{w} ⊙ \tilde{y} ⊙ {l}^{′} ( \tilde{y} ⊙ {K}_{\tilde{X} {X}_{t}^{*}} {\hat{α}}_{t} )$$

$$Sufficient statistics :$$

$${\tilde{X}}_{t} ∈ {ℝ}^{{\tilde{n}}_{t} \times d} , {\tilde{y}}_{t} ∈ {ℝ}^{{\tilde{n}}_{t}} , {\tilde{w}}_{t} ∈ {ℝ}^{{\tilde{n}}_{t}}$$

### Other Embodiment

Although the embodiments of the present disclosure and the detailed examples have been described above, the present disclosure is not limited to the embodiments described above, and various modifications can be made to implement the present disclosure.

For example, in the above embodiments, the compression unit 16 is described as calculating sufficient statistics of past data as information on past data used in learning in the previous stage, but it may not be necessary to calculate sufficient statistics for the information on the past data. In other words, the information on past data needs only to be a statistical quantity of past data that, when the learning unit 14 learns the additional data in the next stage during learning in the next stage, can obtain learning results equivalent to those when the past data acquired in the past by the acquisition unit is used.

In addition, multiple functions of one component in the above embodiment may be implemented by multiple components, or a function of one component may be implemented by multiple components. In addition, multiple functions of multiple components may be implemented by one component, or a single function implemented by multiple components may be implemented by one component. Further, a part of the configuration of the above embodiment may be omitted. At least a part of the configuration of the embodiment may be added to or replaced with another configuration of the embodiment.

In addition to the continual learning system described above, the present disclosure can also be implemented in various forms, such as a system that includes the continual learning system as a component, a program for causing a computer or a processor to function as the continual learning system, a non-transitory tangible storage medium such as a semiconductor memory on which this program is stored, and a continual learning method.

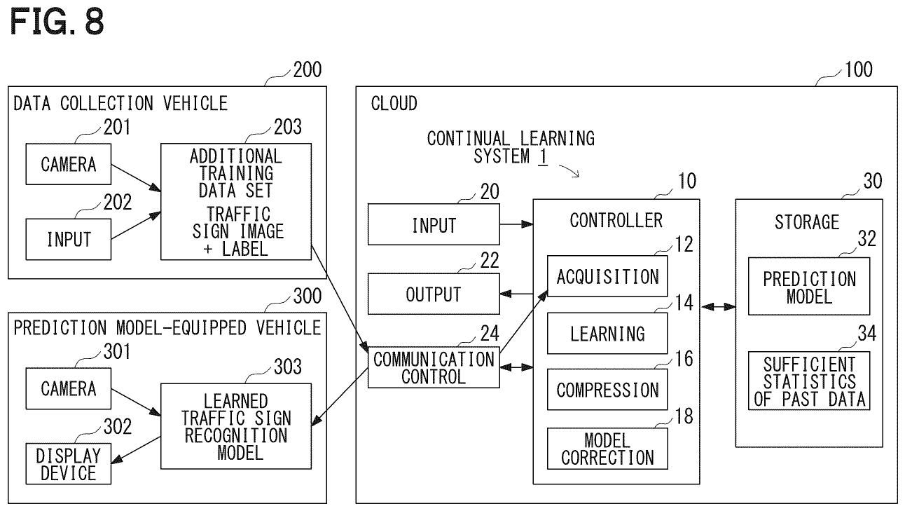

Furthermore, in other embodiments, the continual learning system 1 may operate in cooperation with multiple vehicles. For example, as shown in FIG. 8, a cloud 100 may include the continual learning system 1 and cooperate with a data collection vehicle 200 and a prediction model-equipped vehicle 300. The data collection vehicle 200 acquires images of traffic signs using a camera 201.

In addition, labels for the acquired traffic sign images are provided by a human operator via an input unit 202. The labels indicate, for example, features such as “stop” or other sign information. The data collection vehicle inputs the traffic sign images and labels as an additional training dataset 203 to the communication control unit 24 of the cloud. The acquisition unit 12 of the controller 10 obtains the additional training dataset 203 via the communication control unit 24. The learning unit 14 updates the prediction model 32 based on the acquired additional training dataset 203, the prediction model that is a traffic sign recognition model, and the sufficient statistics 34. Furthermore, the compression unit 16 updates the sufficient statistics 34 based on the acquired additional training dataset 203, the prediction model 32 that is the traffic sign recognition model, and the sufficient statistics 34. The model correction unit 18 modifies the prediction model 32, for example, when the types of traffic signs need to be expanded. With this configuration, the traffic sign recognition model is learned based on the sufficient statistics, and a learned traffic sign recognition model 303 is generated.

Subsequently, the communication control unit 24 outputs (deploys) the learned traffic sign recognition model 303 to the prediction model-equipped vehicle 300. The prediction model-equipped vehicle 300 inputs traffic sign images acquired from a camera 301 into the learned traffic sign recognition model 303, and displays the traffic sign recognition results output by the model on a display device 302 installed in the prediction model-equipped vehicle 300. This allows the occupants of the prediction model-equipped vehicle to confirm the traffic sign recognition results displayed on the display device 302, such as a liquid crystal display.

Additionally, when the output unit 22 of the continual learning system 1 includes a display device, it may also display the calculated statistics on the display device.

What is claimed is:

1. A continual learning system that learns a prediction model that performs prediction on input data, the continual learning system comprising:
an acquisition unit configured to acquire additional data;
a learning unit configured to learn the prediction model based on the additional data, information on past data used for a previous learning stage, and the prediction model learned in the previous learning stage;
a compression unit configured to calculate the information on the past data to be used in a next learning stage by the learning unit based on the additional data, the information on the past data, and the prediction model learned in the previous learning stage by the learning unit; and
a storage that stores the prediction model learned by the learning unit and the information on the past data calculated by the compression unit,
wherein
the learning unit and the compression unit are configured to calculate the prediction model and the information of the past data based on
the additional data,
the prediction model stored in the storage, and
the information on the past data stored in the storage,
when, in the next learning stage, the learning unit further learns, as the information on the past data, the additional data for the next learning stage, the compression unit calculates statistics of the past data, and
the statistics provides a learning result equivalent to a learning result obtained when the acquisition unit uses the past data acquired as the additional data in past by the acquisition unit.

2. The continual learning system according to claim 1, wherein
the compression unit is configured to calculate sufficient statistics of the past data as the statistics of the past data.

3. The continual learning system according to claim 1, wherein
the prediction model includes a fixed feature extractor and a linear predictor.

4. The continual learning system according to claim 2, wherein
the learning unit is configured to learn the prediction model based on the sufficient statistics of the past data calculated by the compression unit together with the additional data.

5. The continual learning system according to claim 1, further comprising
an input unit configured to input an importance ratio of the additional data relative to the past data,
wherein
the compression unit is configured to set a ratio of the past data to the additional data when calculating information on the past data, according to the importance ratio input via the input unit.

6. The continual learning system according to claim 2, wherein
the compression unit is configured to calculate the sufficient statistics of the past data in any one of a matrix format, a synthetic data format in a feature space, and a synthetic data format in an input space.

7. The continual learning system according to claim 6, wherein
when the prediction model is a linear regression model including a fixed feature extractor,
the compression unit calculates exact sufficient statistics of the past data in the matrix format or in the synthetic data format in the feature space as sufficient statistics of the past data.

8. The continual learning system according to claim 6, wherein
when the prediction model is a linear model including a fixed feature extractor, the compression unit is configured to calculate approximate sufficient statistics in the matrix form as sufficient statistics of the past data.

9. The continual learning system according to claim 6, wherein
the compression unit calculates approximate sufficient statistics of a synthetic data format in the input space as sufficient statistics of the past data when the prediction model is a kernel model.

10. The continual learning system according to claim 1, further comprising
a model correction unit configured to change a model configuration of the prediction model depending on a class of the input data.

11. A continual learning method comprising:
learning a prediction model that performs prediction on input data;
acquiring additional data;
learning the prediction model based on the additional data, information on past data used for a previous learning stage, and the prediction model learned in the previous learning stage;
calculating the information on the past data to be used in a next learning stage based on the additional data, the information on the past data, and the prediction model learned in the previous learning stage;
storing the learned prediction model and the calculated information on the past data;
calculating the prediction model and the information of the past data based on
the additional data,
the stored prediction model, and
the stored information on the past data; and
when, in the next learning stage, further learning, as the information on the past data, the additional data for the next learning stage, calculating statistics of the past data,
wherein
the statistics provides a learning result equivalent to a learning result obtained in a case of using the past data acquired in past as the additional data.

12. A continual learning system comprising:
a storage; and
at least one processor with a memory storing computer program code, wherein
the at least one processor with the memory is configured to cause the continual learning system to:
learn a prediction model that performs prediction on input data;
acquire additional data;
learn the prediction model based on the additional data, information on past data used for a previous learning stage, and the prediction model learned in the previous learning stage; and
calculate the information on the past data to be used in a next learning stage based on the additional data, the information on the past data, and the prediction model learned in the previous learning stage,
wherein
the storage stores the learned prediction model and the calculated information on the past data,
the at least one processor with the memory is further configured to cause the continual learning system to:
calculate the prediction model and the information of the past data based on
the additional data,
the prediction model stored in the storage, and
the information on the past data stored in the storage; and
when, in the next learning stage, further learning, as the information on the past data, the additional data for the next learning stage, calculate statistics of the past data, and
the statistics provides a learning result equivalent to a learning result obtained in a case of using the past data acquired in past as the additional data.
